(19) United States
(12) Patent Application Publication
(10) Pub. No.: US 2010/0024727 A1
(43) Pub. Date: Feb. 4, 2010

(54) SHOWERHEAD AND CHEMICAL VAPOR DEPOSITION APPARATUS INCLUDING THE SAME

(75) Inventors: Changsung Sean Kim, Yongin (KR); Young Sun Won, Seoul (KR); Jong Pa Hong, Yongin (KR); Yong Il Kwon, Yongin (KR); Ji Hye Shim, Suwon (KR)

Correspondence Address: MCDERMOTT WILL & EMERY LLP, 600 13TH STREET, N.W., WASHINGTON, DC, 20005-3096, US

(73) Assignee: SAMSUNG ELECTRO-MECHANICS CO., LTD

(21) Appl. No.: 12/407,347

(22) Filed: Mar. 19, 2009

(30) Foreign Application Priority Data
Aug. 4, 2008 (KR) 10-2008-0076157

(51) Int. Cl. C23C 16/44

(52) U.S. Cl. 118/715

(57) ABSTRACT

Provided is a showerhead that can inject a reaction gas into a reaction chamber in a manner such that the injected reaction gas form a spiral vortex flow field. Therefore, the injected reaction gas can be mixed within a shorter distance, and thus the effective deposition radius of a wafer can be increased so that uniform-density deposition can be performed on the entire surface of the wafer using the mixed reaction gas.

### CROSS-REFERENCE TO RELATED APPLICATIONS

This application claims the priority of Korean Patent Application No. 2008-76157 filed on Aug. 4, 2008, in the Korean Intellectual Property Office, the disclosure of which is incorporated herein by reference.

### BACKGROUND OF THE INVENTION

1. Field of the Invention

The present invention relates to a showerhead for chemical vapor deposition (CVD) and a CVD apparatus including the showerhead, and more particularly, to a CVD showerhead having an improved reaction gas injection structure and a CVD apparatus including the CVD showerhead.

2. Description of the Related Art

In general, chemical vapor deposition (CVD) means a method of forming a thin film by supplying a reaction gas to the inside of a reaction chamber and allowing the reaction gas to react with the top surface of a heated wafer. As compared with a liquid phase growth method, such a vapor phase thin film forming method is advantageous because a crystal film having a relatively high quality can be grown; however the crystal growth rate of the vapor phase thin film forming method is relatively low.

In a method widely used for overcoming such a disadvantage, a plurality of substrates are simultaneously processed in one growth cycle.

A CVD apparatus includes a reaction chamber in which a predetermined space is formed, a susceptor installed in the predetermined space of the reaction chamber for receiving a wafer as a deposition target object, a heating unit disposed close to the susceptor for applying heat to the wafer, and a showerhead configured to inject a reaction gas to the wafer mounted on the susceptor.

### SUMMARY OF THE INVENTION

An aspect of the present invention provides a showerhead that can inject a reaction gas into a reaction chamber in a manner such that the injected reaction gas form a spiral vortex flow field in the reaction chamber, so as to mix the injected reaction gas within a shorter distance and increase effective deposition radius for performing a uniform-density deposition on the entire surface of a wafer using the mixed reaction gas.

Another aspect of the present invention provides a showerhead that can inject a reaction gas using fewer injection nozzles and thus can be manufactured with lower costs and less time.

Another aspect of the present invention provides a chemical vapor deposition (CVD) apparatus in which a reaction gas can be mixed within a shorter mixing length for reducing the height of a reaction chamber and the volume of the CVD apparatus.

According to an aspect of the present invention, there is provided a showerhead for CVD, the showerhead including: a head including a reservoir storing an introduced reaction gas and configured to supply the reaction gas stored in the reservoir to a reaction chamber; and a plurality of injection nozzles obliquely formed through a bottom surface of the head at a predetermined angle of attack in predetermined directions so as to inject the reaction gas to the reaction chamber and form a spiral vortex flow field by the injected reaction gas.

The head may include: a first head storing a first reaction gas and injecting the first reaction gas to the reaction chamber; and a second head storing a second reaction gas and injecting the second reaction gas to the reaction chamber.

The showerhead may further include a spacer disposed between the first and second heads for maintaining a predetermined gap between the first and second heads.

The first head may include: a first reservoir storing a first reaction gas; and at least one first injection nozzle configured to inject the first reaction gas stored in the first reservoir to the reaction chamber. The second head may include: a second injection nozzle through which the first injection nozzle is inserted; and a gas flow path formed between the second injection nozzle and the first injection nozzle inserted through the second injection nozzle, so as to inject a second reaction gas to the reaction chamber.

The first and second injection nozzles may be inclined at a predetermined angle of attack in a predetermined direction such that the first and second reaction gases injected to the reaction chamber form a spiral vortex flow field.

The first and second injection nozzles may be oriented such that the first and second reaction gases injected to the reaction chamber have a flowing direction opposite to a rotation direction of a susceptor disposed inside the reaction chamber.

The gas flow path may include a gap having a predetermined size and formed between an inner surface of the second injection nozzle and an outer surface of the first injection nozzle.

The first injection nozzle may be substantially coaxial with the second injection nozzle.

Bottom ends of the first and second injection nozzles may be located substantially at the same horizontal level.

According to another aspect of the present invention, there is provided a CVD apparatus including: a reaction chamber including a susceptor; a head including a reservoir storing an introduced reaction gas and configured to supply the reaction gas stored in the reservoir to a reaction chamber; and a plurality of injection nozzles obliquely formed through a bottom surface of the head at a predetermined angle of attack in predetermined directions so as to inject the reaction gas to the reaction chamber and form a spiral vortex flow field by the injected reaction gas.

The head may include: a first head storing a first reaction gas and injecting the first reaction gas to the reaction chamber; a second head storing a second reaction gas and injecting the second reaction gas to the reaction chamber; and a spacer disposed between the first and second heads for maintaining a predetermined gap between the first and second heads.

The first head may include: a first reservoir storing a first reaction gas; and at least one first injection nozzle configured to inject the first reaction gas stored in the first reservoir to the reaction chamber. The second head may include: a second injection nozzle through which the first injection nozzle is inserted; and a gas flow path formed between the second injection nozzle and the first injection nozzle inserted through the second injection nozzle, so as to inject a second reaction gas to the reaction chamber.

The first and second injection nozzles may be inclined at a predetermined angle of attack in a predetermined direction such that the first and second reaction gases injected to the reaction chamber form a spiral vortex flow field.

The first and second injection nozzles may be oriented such that the first and second reaction gases injected to the reaction chamber have a flowing direction opposite to a rotation direction of the susceptor disposed inside the reaction chamber.

The gas flow path may include a gap having a predetermined size and formed between an inner surface of the second injection nozzle and an outer surface of the first injection nozzle.

### BRIEF DESCRIPTION OF THE DRAWINGS

The above and other aspects, features and other advantages of the present invention will be more clearly understood from the following detailed description taken in conjunction with the accompanying drawings, in which:

FIG. 1 is a cross-sectional view illustrating a chemical vapor deposition (CVD) apparatus according to an embodiment of the present invention;

FIG. 2 is a schematic cut-away perspective view illustrating a showerhead of the CVD apparatus of FIG. 1;

FIG. 3 is a cross-sectional view illustrating a chemical vapor deposition (CVD) apparatus according to another embodiment of the present invention;

FIG. 4 is a schematic cut-away perspective view illustrating a showerhead of the CVD apparatus of FIG. 3; and

FIG. 5 is a perspective view illustrating disassembled first and second heads of the showerhead illustrated in FIG. 4.

### DETAILED DESCRIPTION OF THE PREFERRED EMBODIMENT

A showerhead for chemical vapor deposition (CVD) and a CVD apparatus including the showerhead will now be described in detail with reference to the accompanying drawings, in which exemplary embodiments of the present invention are shown.

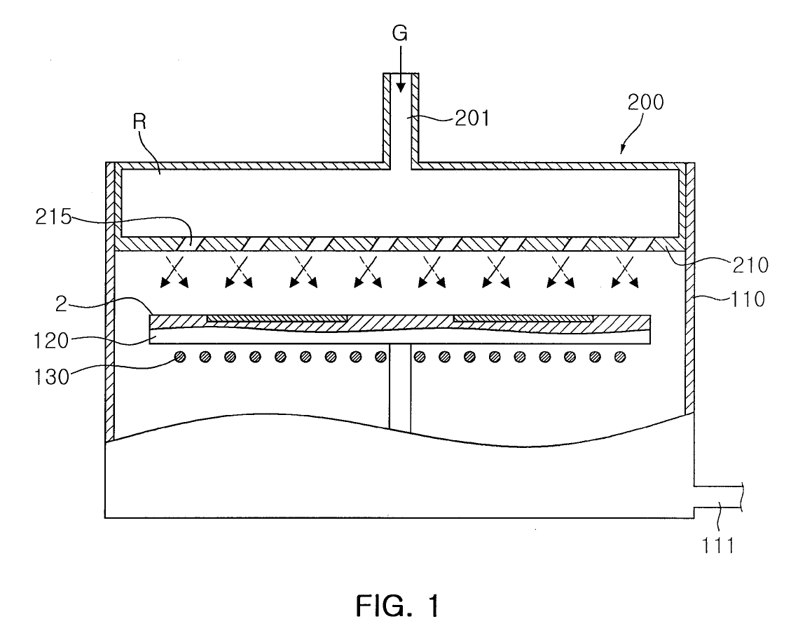

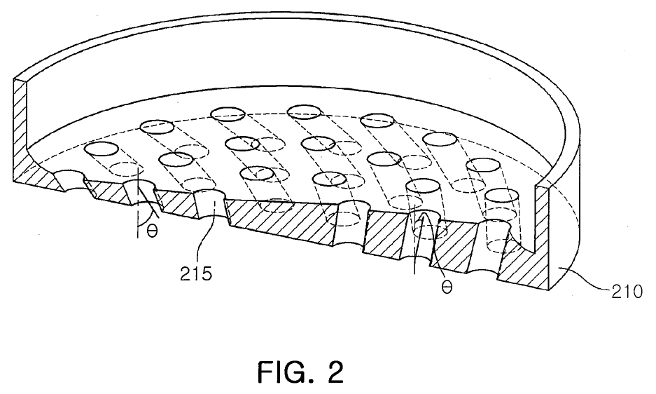

First, a CVD apparatus including a showerhead for CVD will now be described with reference to FIGS. 1 and 2 according to an embodiment of the present invention.

FIG. 1 is a cross-sectional view illustrating a CVD apparatus according to an embodiment of the present invention, and FIG. 2 is a schematic cut-away perspective view illustrating a showerhead of the CVD apparatus of FIG. 1.

Referring to FIGS. 1 and 2, the CVD apparatus of the current embodiment includes a reaction chamber 110, a susceptor 120, a heating unit 130, and a showerhead 200.

The reaction chamber 110 includes a predetermined inner space so that chemical vapor reaction can be carried out inside the reaction chamber 110 between a reaction gas introduced into the inner space and a wafer 2 (deposition target object). An insulating material resistant to a high temperature may be provided on an inner surface of the reaction chamber 110.

An exhaust hole 111 is formed at the reaction chamber 110 for discharging gas to the outside of the reaction chamber 110 after a chemical vapor reaction between the gas and the wafer 2.

The susceptor 120 is a wafer supporting structure, which is rotatably installed inside the reaction chamber 110 and includes at least one recessed pocket at a top surface for receiving a wafer 2.

The susceptor 120 is formed of graphite and has a disk shape. The susceptor 120 includes a rotation shaft at a bottom center portion, and the rotation shaft is connected to a driving motor (not shown) so that the susceptor 120 on which the wafer 2 is placed can be rotated by the driving motor in one direction at a constant speed of about 5 rpm to about 50 rpm.

The heating unit 130 is disposed close to the bottom surface of the susceptor 120 to supply heat to the susceptor 120 and thus heat the wafer 2 placed on the susceptor 120.

The heating unit 130 may be one of an electric heater, a high-frequency induction heater, an infrared radiation heater, and a laser heater.

A temperature sensor (not shown) may be disposed inside the reaction chamber 110 at a position close to the susceptor 120 or the heating unit 130 for monitoring the inside temperature of the reaction chamber 110 and controlling the heating temperature of the heating unit 130 based on the monitored temperature.

The showerhead 200 is a structure installed at an upper region of the reaction chamber 110 for injecting at least one kind of reaction gas G to the wafer 2 placed on the susceptor 120 in a manner such that the injected reaction gas G can make uniform contact with the wafer 2. The showerhead 200 includes a head 210 and injection nozzles 215.

The head 210 includes at least one reservoir R, which is connected to a supply line 201 for receiving a reaction gas G from an outer source and storing the received reaction gas.

The reaction gas G stored in the reservoir R is supplied to the reaction chamber 110.

The injection nozzles 215 are formed through a bottom surface of the head 210 so that the reaction gas G stored inside the reservoir R can be injected to the inside of the reaction chamber 110 through the injection nozzles 215.

Exemplary structures of the injection nozzles 215 of the showerhead 200 will now be described in detail with reference to FIG. 2.

As shown in FIG. 2, the injection nozzles 215 are obliquely formed through the bottom surface of the head 210 at a predetermined angle of attack θ in predetermined directions so that a reaction gas injected into the reaction chamber 110 through the injection nozzles 215 can form a spiral vortex flow field.

That is, although injection nozzles are straightly formed down to a lower susceptor in the related art, the injection nozzles 215 of the current embodiment are obliquely formed at a predetermined angle of attack θ so that a reaction gas injected through the injection nozzles 215 can flow clockwise or counterclockwise along a circular spiral path.

Therefore, a reaction gas injected through the injection nozzles 215 forms a spiral vortex moving down to the susceptor 120 disposed at a lower side of the reaction chamber 110.

The injection nozzles 215 may be inclined from the center portion to the circumferential portion of the bottom surface of the head 210 to form a vortex field inside the reaction chamber 110, and the direction of a reaction gas flow in the vortex is opposite to the rotation direction of the susceptor 120 inside the reaction chamber 110.

Therefore, according to the current embodiment, a reaction gas can be sufficiently mixed using a fewer injection nozzles as compared with the number of injection nozzles necessary in the related art.

In addition, the flow of injected reaction gas can be controlled by adjusting the angle of attack θ of the injection nozzles 215 to reduce a reaction gas mixing length. Therefore, a smaller CVD apparatus can be provided.

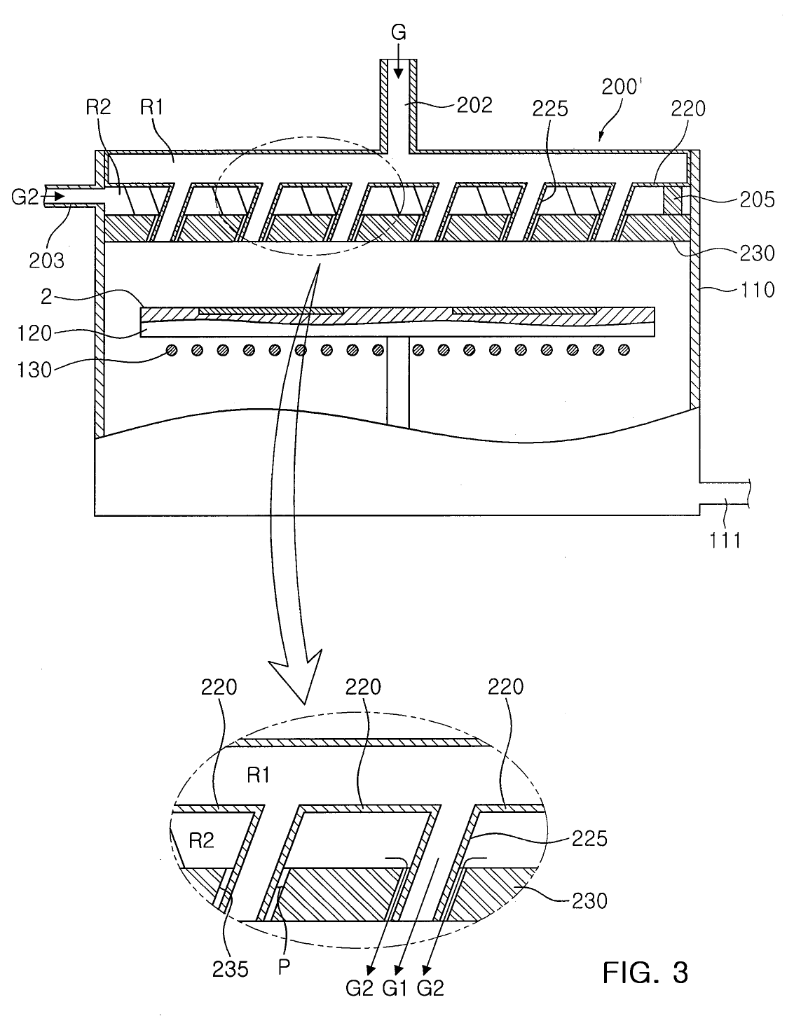

A CVD apparatus including a showerhead 200′ for CVD will now be described with reference to FIGS. 3 to 5 according to another embodiment of the present invention.

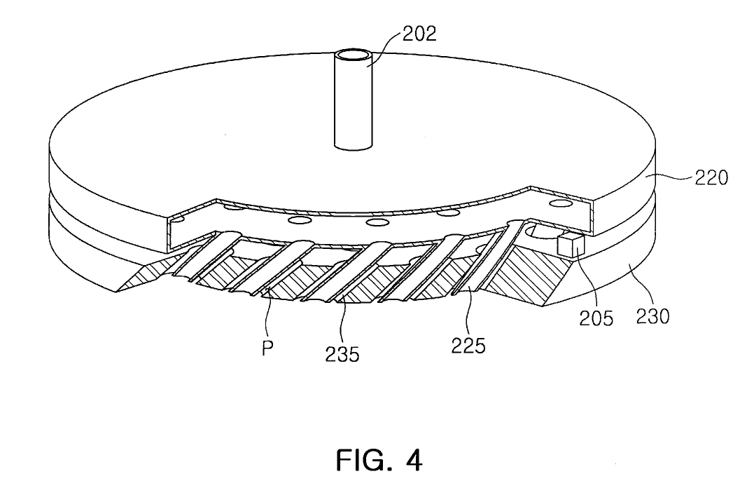

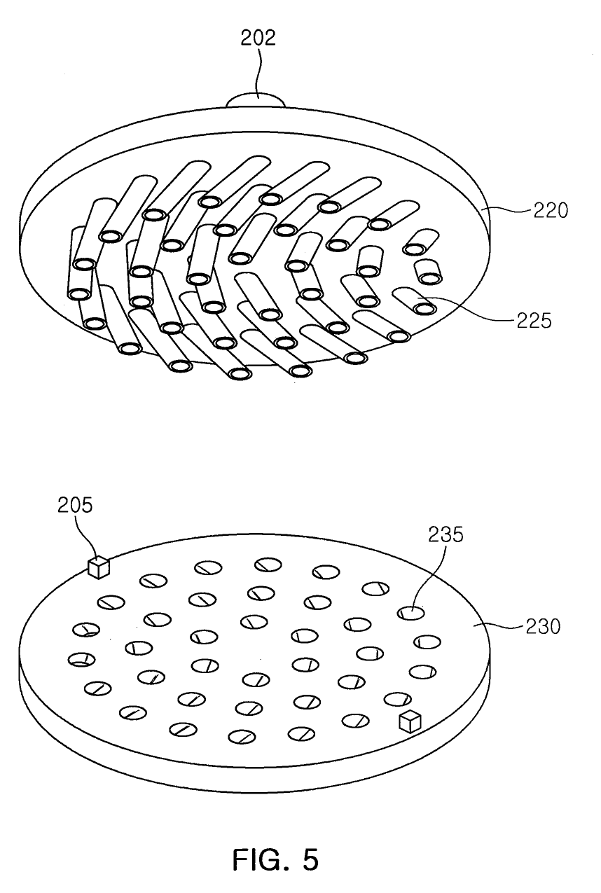

FIG. 3 is a cross-sectional view illustrating a CVD apparatus according to another embodiment of the present invention, FIG. 4 is a schematic cut-away perspective view illustrating the showerhead 200′ of the CVD apparatus of FIG. 3, and FIG. 5 is a perspective view illustrating disassembled first and second heads of the showerhead 200′ illustrated in FIG. 4.

The CVD apparatus of the current embodiment illustrated in FIGS. 3 to 5 has substantially the same structure as the CVD apparatus of the previous embodiment illustrated in FIGS. 1 and 2.

However, the showerhead 200′ of the current embodiment has a structure different from that of the showerhead 200 of the previous embodiment illustrated in FIGS. 1 and 2. Thus, in the following description, descriptions of the same elements will be omitted, and the showerhead 200′ will be mainly described in detail.

Referring to FIG. 3, in the current embodiment, the showerhead 200′ for CVD includes a first head 220, a second head 230, and spacers 205 disposed between the first and second heads 220 and 230 for maintaining a predetermined gab between the first and second heads 220 and 230.

The first head 220 includes a first reservoir R1, which is connected to a first supply line 202 for receiving a first reaction gas G1 and storing the received first reaction gas G1.

At least one first injection nozzle 225 having a predetermined length is provided at a bottom surface of the first head 220 so that the first reaction gas G1 stored in the first reservoir R1 can be injected to the inside of a reaction chamber 110 through the first injection nozzle 225.

The first injection nozzle 225 protrudes obliquely at a predetermined angle of attack θ in a predetermined direction so that a reaction gas injected into the reaction chamber 110 through the first injection nozzle 225 can form a spiral vortex flow field like in the previous embodiment.

That is, although an injection nozzle is straightly formed down to a lower susceptor in the related art, the first injection nozzle 225 of the current embodiment protrudes obliquely at a predetermined angle of attack θso that a reaction gas injected through the first injection nozzle 225 can flow clockwise or counterclockwise along a circular spiral path.

Therefore, the first reaction gas G1 injected through the injection nozzle 225 forms a spiral vortex moving down to a susceptor 120 disposed at a lower side of the reaction chamber 110.

The first injection nozzle 225 may be composed of a hollow gas pipe for injecting the first reaction gas G1.

The second head 230 is disposed under the first head 220 and faces the susceptor 120, and the spacers 205 maintain a predetermined gap between the first and second heads 220 and 230 to form a second reservoir R2 having a predetermined size.

The second reservoir R2 communicates with a second supply line 203 for receiving a second reaction gas G2 through the second supply line 203 and storing the received second reaction gas G2.

As shown in FIGS. 3(b) and 4, second injection nozzles 235 having a predetermined size are provided at the second head 230 so that the first injection nozzles 225 can be inserted through the second injection nozzles 235 with a predetermined gap between outer surfaces of the first injection nozzles 225 and inner surfaces of the second injection nozzles 235.

Similar to the first injection nozzles 225, the second injection nozzles 235 are obliquely formed at the angle of attack θ in the same directions as the first injection nozzles 225 so that a reaction gas injected into the reaction chamber 110 can form a spiral vortex flow field.

Therefore, the first injection nozzles 225 can be coupled to the second injection nozzles 235 by inserting the first injection nozzles 225 through the second injection nozzles 235.

The second injection nozzles 235 are formed of predetermined holes for receiving the gas pipes of the first injection nozzles 225, and the number of the second injection nozzles 235 may be equal to the number of the first injection nozzles 225.

Since predetermined gaps are formed between the second injection nozzles 235 and the first injection nozzles 225 inserted through the second injection nozzles 235, gas flow paths P can be formed by the predetermined gaps so that the second reaction gas G2 stored in the second reservoir R2 can be injected to the inside of the reaction chamber 110 through the gas flow paths P.

Therefore, the first reaction gas G1 supplied through the first supply line 202 and stored in the first reservoir R1 is injected to the inside of the reaction chamber 110 through the gas pipes of the first injection nozzles 225, and the second reaction gas G2 supplied through the second supply line 203 and stored in the second reservoir R2 is injected to the inside of the reaction chamber 110 through the gas flow paths P, so that the first and second reaction gases can be mixed with each other under the first and second injection nozzles 225 and 235.

The first injection nozzles 225 may be substantially coaxial with the second injection nozzles 235 to inject the second reaction gas G2 through the gas flow paths P more uniformly.

In addition, bottom ends of the first injection nozzles 225, and bottom ends of the second injection nozzles 235 are located substantially at the same horizontal level as the bottom surface of the second head 230 so that the second reaction gas G2 injected through the gas flow paths P can be mixed with the first reaction gas GI injected through the first injection nozzles 225 more uniformly.

Like the injection nozzles 215 of the previous embodiment, the first and second injection nozzles 225 and 235 may be oriented to inject the first and second reaction gases G1 and G2 in a direction opposite to the rotation direction of the susceptor 120 inside the reaction chamber 110.

In this case, the speed of a gas flow in a spiral flow field can be increased, and thus reaction gases can be sufficiently mixed within a relatively short flow length.

However, the present invention is not limited thereto. For example, first and second reaction gases can be injected in the same direction as the rotation direction of the susceptor 120.

According to the present invention, reaction gas injected through the injection nozzles form a spiral vortex flow field such that the reaction gas can be mixed within a shorter distance. Therefore, the reaction gas can be less consumed, and a film having a uniform density can be grown using the reaction gas.

Furthermore, reaction gas can be injected using fewer injection nozzles owing the above-described improved structure, and thus the manufacturing costs and time can be reduced owing to the reduced number of injection nozzles.

In addition, since a distance of the reaction chamber necessary for mixing different reaction gases can be reduced, the height of the reaction chamber can be reduced, and thus a smaller CVD apparatus can be provided.

While the present invention has been shown and described in connection with the exemplary embodiments, it will be apparent to those skilled in the art that modifications and variations can be made without departing from the spirit and scope of the invention as defined by the appended claims.

What is claimed is:

1. A showerhead for CVD (chemical vapor deposition), comprising:
a head comprising a reservoir storing an introduced reaction gas, the head being configured to supply the reaction gas stored in the reservoir to a reaction chamber; and
a plurality of injection nozzles obliquely formed through a bottom surface of the head at a predetermined angle of attack in predetermined directions so as to inject the reaction gas to the reaction chamber and form a spiral vortex flow field by the injected reaction gas.

2. The showerhead of claim 1, wherein the head comprises:
a first head storing a first reaction gas and injecting the first reaction gas to the reaction chamber; and
a second head storing a second reaction gas and injecting the second reaction gas to the reaction chamber.

3. The showerhead of claim 2, further comprising a spacer disposed between the first and second heads for maintaining a predetermined gap between the first and second heads.

4. The showerhead of claim 2, wherein the first head comprises:
a first reservoir storing a first reaction gas; and
at least one first injection nozzle configured to inject the first reaction gas stored in the first reservoir to the reaction chamber,
wherein the second head comprises:
a second injection nozzle through which the first injection nozzle is inserted; and
a gas flow path formed between the second injection nozzle and the first injection nozzle inserted through the second injection nozzle, so as to inject a second reaction gas to the reaction chamber.

5. The showerhead of claim 4, wherein the first and second injection nozzles are inclined at a predetermined angle of attack in a predetermined direction such that the first and second reaction gases injected to the reaction chamber form a spiral vortex flow field.

6. The showerhead of claim 4, wherein the first and second injection nozzles are oriented such that the first and second reaction gases injected to the reaction chamber have a flowing direction opposite to a rotation direction of a susceptor disposed inside the reaction chamber.

7. The showerhead of claim 4, wherein the gas flow path comprises a gap having a predetermined size and formed between an inner surface of the second injection nozzle and an outer surface of the first injection nozzle.

8. The showerhead of claim 4, wherein the first injection nozzle is substantially coaxial with the second injection nozzle.

9. The showerhead of claim 4, wherein bottom ends of the first and second injection nozzles are located substantially at the same horizontal level.

10. A CVD apparatus comprising:
a reaction chamber comprising a susceptor;
a head comprising a reservoir storing an introduced reaction gas, the head being configured to supply the reaction gas stored in the reservoir to a reaction chamber; and
a plurality of injection nozzles obliquely formed through a bottom surface of the head at a predetermined angle of attack in predetermined directions so as to inject the reaction gas to the reaction chamber and form a spiral vortex flow field by the injected reaction gas.

11. The CVD apparatus of claim 10, wherein the head comprises:
a first head storing a first reaction gas and injecting the first reaction gas to the reaction chamber;
a second head storing a second reaction gas and injecting the second reaction gas to the reaction chamber; and
a spacer disposed between the first and second heads for maintaining a predetermined gap between the first and second heads.

12. The CVD apparatus of claim 11, wherein the first head comprises:
a first reservoir storing a first reaction gas; and
at least one first injection nozzle configured to inject the first reaction gas stored in the first reservoir to the reaction chamber,
wherein the second head comprises:
a second injection nozzle through which the first injection nozzle is inserted; and
a gas flow path formed between the second injection nozzle and the first injection nozzle inserted through the second injection nozzle so as to inject a second reaction gas to the reaction chamber.

13. The CVD apparatus of claim 12, wherein the first and second injection nozzles are inclined at a predetermined angle of attack in a predetermined direction such that the first and second reaction gases injected to the reaction chamber form a spiral vortex flow field.

14. The CVD apparatus of claim 12, wherein the first and second injection nozzles are oriented such that the first and second reaction gases injected to the reaction chamber have a flowing direction opposite to a rotation direction of the susceptor disposed inside the reaction chamber.

15. The CVD apparatus of claim 12, wherein the gas flow path comprises a gap having a predetermined size and formed between an inner surface of the second injection nozzle and an outer surface of the first injection nozzle.
